(19) United States
(12) Patent Application Publication
(10) Pub. No.: US 2023/0005513 A1
(43) Pub. Date: Jan. 5, 2023

(54) INTERFACE TRANSFORMER AND MULTIPORT STORAGE DEVICE

(71) Applicant: SONIC STAR GLOBAL LIMITED, ROAD TOWN (VG)

(72) Inventors: I-HAN HUANG, ZHUBEI CITY (TW); CHIH-CHIEH CHIU, HSINCHU CITY (TW)

(21) Appl. No.: 17/501,997

(22) Filed: Oct. 14, 2021

Related U.S. Application Data
(60) Provisional application No. 63/217,887, filed on Jul. 2, 2021.

(51) Int. Cl. G11C 7/10; H03K 3/037; H03K 19/20; G11C 11/419; G11C 7/22; G06F 1/06

(52) U.S. Cl. CPC G11C 7/1075; H03K 3/037; H03K 19/20; G11C 11/419; G11C 7/222; G06F 1/06

(57) ABSTRACT

The present application discloses an interface transformer. The interface transformer includes a first clock generator, a combinational circuit, and a second clock generator. The first clock generator generates an intermediate clock signal according to an input clock signal. A rising edge of the input clock signal precedes a rising edge of the intermediate clock signal, and a falling edge of the intermediate clock signal precedes a falling edge of the input clock signal. The combinational circuit generates a mask clock signal by delaying the intermediate clock signal. The second clock generator generates a transformed clock signal according to the input clock signal and the mask clock signal. The transformed clock signal has two pulses within a cycle of the input clock signal.

### CROSS REFERENCE

This application claims priority to U.S. Provisional Application No. 63/217,887, filed on Jul. 2, 2021, the entire disclosure of which is incorporated herein by reference.

### TECHNICAL FIELD

The present disclosure relates to an interface transformer, and more particularly, to an interface transformer that transforms a one-port storage device into a pseudo two-port storage device.

### DISCUSSION OF THE BACKGROUND

Static random-access memory (SRAM) is a type of volatile memory that offers a simple and fast data access model. In contrast to dynamic random-access memory (DRAM) cells, an SRAM cell can use a latch to store data; therefore, no refresh process is needed, and power consumption is rather low when the device is idle. However, while the DRAM cell can be implemented by one single transistor, the SRAM cell may include more transistors and thus require more area.

In addition, to increase access speed of the SRAM, two-port SRAM cells have been developed to provide a two-read, two-write, or one-read-one-write operation within one system clock cycle. However, the two-port SRAM cell requires even more transistors than the one-port SRAM cells. Consequently, the two-port SRAM cell occupies an increasingly large area in the system as memory requirements increase. Therefore, developing a way to improve the access speed without excessively increasing the area occupied by the SRAM cell has become an important issue that needs to be solved.

### SUMMARY

One embodiment of the present disclosure provides an interface transformer. The interface transformer includes a first clock generator, a combinational circuit, and a second clock generator. The first clock generator is configured to generate an intermediate clock signal according to at least an input clock signal, in which a rising edge of the input clock signal precedes a rising edge of the intermediate clock signal, and a falling edge of the intermediate clock signal precedes a falling edge of the input clock signal. The combinational circuit is configured to generate a mask clock signal by at least delaying the intermediate clock signal. The second clock generator is configured to generate a transformed clock signal according to at least the input clock signal and the mask clock signal. The transformed clock signal has a first pulse and a second pulse arising within a cycle of the input clock signal.

Another embodiment of the present disclosure provides a pseudo multiport storage device. The pseudo multiport storage device includes the aforementioned interface transformer and a storage circuit. The storage circuit is coupled to the interface transformer, and is configured to perform read operations and write operations according to the transformed clock signal.

Since the interface transformer and the multiport storage device can generate a transformed clock signal having double pulses within a cycle of the input clock signal, the storage circuit is able to perform more operations within each cycle of the input clock signal.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a pseudo multiport storage device according to one embodiment of the present disclosure.

FIG. 2 shows a timing diagram of clock signals processed by an interface transformer of the pseudo multiport storage device in FIG. 1.

FIG. 3 shows a first clock generator of the pseudo multiport storage device in FIG. 1 according to one embodiment of the present disclosure.

FIG. 4 shows a timing diagram of signals received and transmitted by the first clock generator.

FIG. 5 shows a second clock generator of the pseudo multiport storage device in FIG. 1 according to one embodiment of the present disclosure.

FIG. 6 shows a timing diagram of signals received and transmitted by the second clock generator.

FIG. 7 shows a pseudo multiport storage device according to another embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

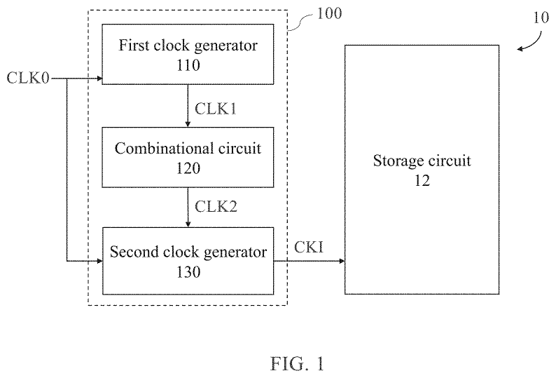

FIG. 1 shows a pseudo multiport storage device 10 according to one embodiment of the present disclosure. The pseudo multiport storage device 10 includes an interface transformer 100 and a storage circuit 12. In some embodiments, the storage circuit 12 can be a register file or a static random-access memory (SRAM), and can include a plurality of one-port SRAM cells.

In the present embodiment, when the pseudo multiport storage device 10 receives an input clock signal CLK0, the interface transformer 100 can transform the input clock signal CLK0 into a transformed clock signal CKI that has a higher frequency so that the storage circuit 12 can perform read operations and write operations according to the transformed clock signal CKI with a higher speed.

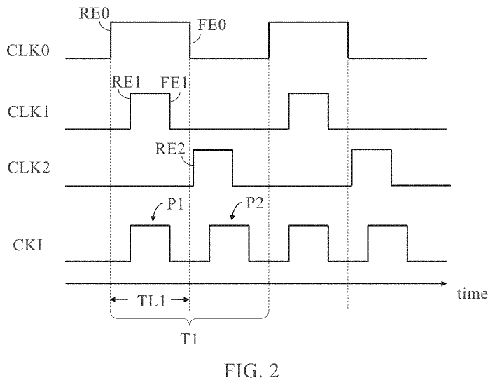

FIG. 2 shows a timing diagram of the clock signals processed by the interface transformer 100. As shown in FIG. 2, the transformed clock signal CKI can have two pulses P1 and P2 within a cycle duration T1 of the input clock signal CLK0. In such case, although the storage circuit 12 is a one-port storage circuit 12 that performs one read operation or one write operation at a time, the storage circuit 12 can perform two operations, such as one read operation and one write operation, according to the two pulses P1 and P2 of the transformed clock signal CKI, during one single cycle of the input clock signal CLK0. That is, the interface transformer 100 can generate the transformed clock signal CKI with a higher frequency according to the input clock signal CLK0 so that the storage circuit 12 can perform two operations consecutively within one cycle of the input clock signal CLK0. As a result, the pseudo multiport storage device 10 can have a function similar to that of a two-port storage device, and can be used as a pseudo two-port storage device.

In the present embodiment, the pseudo multiport storage device 10 can perform a read operation according to the first pulse P1 and a write operation according to the second pulse P2 when operating in the read-write mode. However, the pseudo multiport storage device 10 can also perform a single operation in one cycle of the input clock signal CLK0. For example, in a read mode, the storage device 10 may perform a read operation according to the first pulse P1 and be idle during the second pulse P2. In addition, when operating in a write mode, the storage device 10 can perform a write operation according to the second pulse P2 and be idle during the first pulse PT.

As shown in FIG. 1, the interface transformer 100 includes a first clock generator 110, a combinational circuit 120, and a second clock generator 130. The first clock generator 110 can generate an intermediate clock signal CLK1 according to at least the input clock signal CLK0. In the present embodiment, as shown in FIG. 2, a rising edge RE0 of the input clock signal CLK0 precedes a rising edge RET of the intermediate clock signal CLK1. On the other hand, a falling edge FET of the intermediate clock signal CLK1 precedes a falling edge FE0 of the input clock signal CLK0.

The combinational circuit 120 can receive the intermediate clock signal CLK1 and generate a mask clock signal CLK2 according to the intermediate clock signal CLK1. For example, the combinational circuit 120 may include one or more delay units to generate the mask clock signal CLK2 from the intermediate clock signal CLK1. In some embodiments, the combinational circuit 120 may further include a chopping unit for adjusting the pulse width of the mask clock signal CLK2 according 30 to system requirements.

The second clock generator 130 can generate a transformed clock signal CKI according to at least the input clock signal CLK0 and the mask clock signal CLK2. As shown in FIG. 2, the transformed clock signal CKI has a first pulse P1 and a second pulse P2 within the cycle duration T1 of the input clock signal CLK0. In the present embodiment, the first pulse P1 can be produced according to the rising edge RE0 of the input clock signal CLK0 during a first time interval TL1 in which the input clock signal CLK0 is at a high voltage. In addition, the second pulse P2 is produced according to the rising edge RE2 of the mask clock signal CLK2. Furthermore, a duration of the first pulse P1 and a duration of the second pulse P2 are both less than a duration of the first time interval TL1. Consequently, the interface transformer 100 can generate the transformed clock signal CKI having double pulses in each cycle of the input clock signal CLK0, and the storage circuit 12 can perform a read operation and a write operation according to the two pulses of the transformed clock signal CKI within each cycle of the input clock signal CLK0.

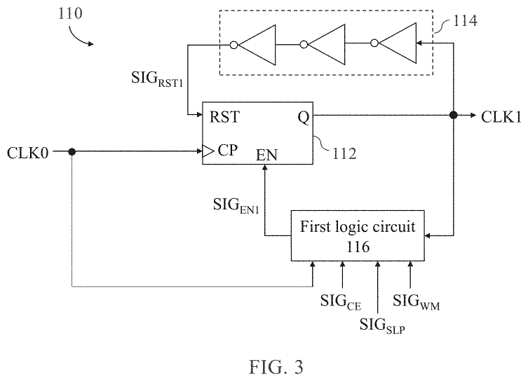

FIG. 3 shows the first clock generator 110 according to one embodiment of the present disclosure. The first clock generator 110 includes a first latch circuit 112. The first latch circuit 112 includes a clock positive terminal CP for receiving the input clock signal CLK0, a reset terminal RST for receiving a first reset signal SIG_{RST1}, and an output terminal Q for outputting the intermediate clock signal CLK1.

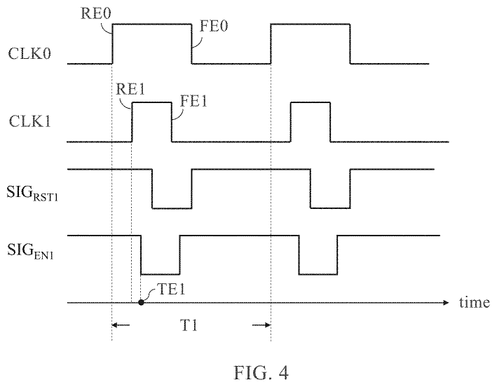

FIG. 4 shows a timing diagram of the signals received and transmitted by the first clock generator 110. In the present embodiment, the first latch circuit 112 can be triggered by the rising edge RE0 of the input clock signal CLK0 to generate a rising edge RE1 of the intermediate clock signal CLK1. Therefore, as shown in FIG. 4, the rising edge RE1 of the intermediate clock signal CLK1 is produced after the rising edge RE0 of the input clock signal CLK0. In addition, after the rising edge RE1 is produced, the first latch circuit 112 can be reset and generate the falling edge FE1 of the intermediate clock signal CLK1 when the first reset signal SIG_{RST1} changes from a high voltage to a low voltage.

As shown in FIG. 3, the first clock generator 110 can further include a first delay and inverse circuit 114. The first delay and inverse circuit 114 can generate the first reset signal SIG_{RST1} by delaying and inverting the intermediate clock signal CLK1. For example, the first delay and inverse circuit 114 may include (N+1) inverters. N is a positive even integer and can be determined according to the desired length of delay. In such case, the first reset signal SIG_{RST1} changes from the high voltage to the low voltage after the rising edge RET of the intermediate clock signal CLK1 has been produced for a period thanks to the first delay and inverse circuit 114. When the first reset signal SIG_{RST1} changes to the low voltage, the first latch circuit 112 is reset to have its output become logic “0” and thus generates the falling edge FET of the intermediate clock signal CLK1.

In the present embodiment, the first clock generator 110 can generate the intermediate clock CLK1 according to the input clock signal CLK0 and the first reset signal SIG_{RST1} by utilizing a self-propagation scheme. Furthermore, the first latch circuit 112 can include an enable terminal EN for receiving a first enable signal SIG_{EN1}. The first enable signal SIG_{EN1} can be used to control whether the first latch circuit 112 is allowed to sense the input clock signal CLK0. For example, the first latch circuit 112 can sense the edges of the input clock signal CLK0 when the first enable signal SIG_{EN1} is at the high voltage, and the first latch circuit 112 can stop sensing the edges of the input clock signal CLK0 when the first enable signal SIG_{EN1} is at the low voltage.

As shown in FIG. 3, the first clock generator 110 can further include a first logic circuit 116 for generating the first enable signal SIG_{EN1} according to at least the input clock signal CLK0 and the intermediate clock signal CLK1. In the present embodiment, the first enable signal SIG_{EN1} can change from the high voltage to the low voltage at a time point TE1 after the rising edge RE0 of the input clock signal CLK0 has been produced for a delay period. Therefore, the first latch circuit 112 will stop sensing the input clock signal CLK0 after the rising edge RET of the intermediate clock signal CLK1 occurs, ensuring that the falling edge FE1 of the intermediate clock signal CLK1 can be controlled by the first reset signal SIG_{RST1}. Subsequently, the first enable signal SIG_{EN1} can change from the low voltage to the high voltage before the next rising edge of the input clock signal CLK0 occurs.

In some embodiments, to further control the first latch circuit 112, the first logic circuit 116 may receive some other system signals and enable the first latch circuit 112 only when needed. For example, a sleep signal SIG_{SLP} for indicating the sleep mode, a chip enable signal SIG_{CE} for enabling the storage circuit 12, and a write multiplex signal SIG_{WM} for indicating the read/write operation mode may also be adopted by the first logic circuit 116 for generating the first enable signal SIG_{EN1} with the desired waveform.

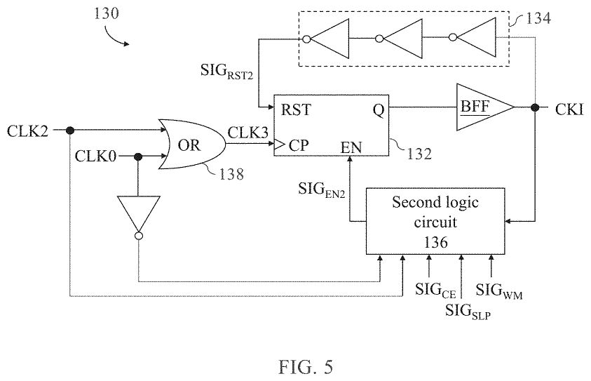

FIG. 5 shows the second clock generator 130 according to one embodiment of the present disclosure. The first clock generator 110 and the second clock generator 130 have similar structures. For example, the second clock generator 130 includes a second latch circuit 132, a second delay and inverse circuit 134, and a second logic circuit 136. However, the second clock generator 130 further includes an OR logic circuit 138.

The OR logic circuit 138 can generate a combined clock signal CLK3 according to the input clock signal CLK0 and the mask clock signal CLK2. In such case, the combined clock signal CLK3 changes to the high voltage when the input clock signal CLK0 or the mask clock signal CLK2 is at the high voltage.

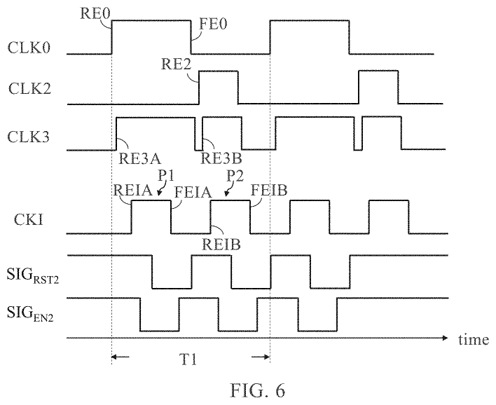

The second latch circuit 132 includes a clock positive terminal CP for receiving the combined clock signal CLK3, a reset terminal for receiving a second reset signal SIG_{RST2}, and an output terminal for outputting the transformed clock signal CKI. FIG. 6 shows a timing diagram of the signals received and transmitted by the second clock generator 130.

In the present embodiment, when the second latch circuit 132 senses the rising edge RE3A of the combined clock signal CLK3 that corresponds to the rising edge RE0 of the input clock signal CLK0, the second latch circuit 132 is triggered to generate a rising edge REIA of the first pulse P1 of the transformed clock signal CKI.

Since the second delay and inverse circuit 134 can generate the second reset signal SIG_{RST2} by delaying and inverting the transformed clock signal CKI, the second delay and inverse circuit 134 changes the second reset signal SIG_{RST2} from the high voltage to the low voltage after the rising edge REIA is produced. As a result, the second latch circuit 132 is reset to have its output turn into logic “0”, thereby producing a falling edge FEIA of the first pulse P1 of the transformed clock signal CKI. Furthermore, after the falling edge FEIA of the transformed clock signal CKI is produced, the second delay and inverse circuit 134 changes the second reset signal SIG_{RST2} from the low voltage back to the high voltage so as to release the second latch circuit 132 from the reset state.

After the first pulse P1 is produced, the second latch circuit 132 senses the following rising edge RE3B of the combined clock signal CLK3 that corresponds to the rising edge RE2 of the mask clock signal CLK2, and the second latch circuit 132 is triggered to generate a rising edge REIB of the second pulse P2 of the transformed clock signal CKI. In addition, after the rising edge REIB of the transformed clock signal CKI is produced, the second delay and inverse circuit 134 changes the second reset signal SIG_{RST2} from the high voltage to the low voltage again. In response, the second latch circuit 132 is reset and its output turns into logic “0”, thereby producing a falling edge FEIB of the second pulse P2 of the transformed clock signal CKI. As a result, the transformed clock signal CKI having double pulses within one cycle of the input clock CLK0 can be generated.

In the present embodiment, the second latch circuit 132 can further include an enable terminal EN for receiving a second enable signal SIG_{EN2}. The second enable signal SIG_{EN2} can be used to control whether the second latch circuit 132 is allowed to sense the combined clock signal CLK3. For example, the second latch circuit 132 can sense the edges of the combined clock signal CLK3 when the second enable signal SIG_{EN2} is at the high voltage, and stop sensing the edges of the combined clock signal CLK3 when the second enable signal SIG_{EN2} is at the low voltage.

As shown in FIG. 5, the second logic circuit 136 can generate the second enable signal SIG_{EN2} according to at least the input clock signal CLK0 and the transformed clock signal CKI. In the present embodiment, the second enable signal SIG_{EN2} can change from the high voltage to the low voltage after the rising edge RE0 of the input clock signal CLK0 has been produced for a delay period. Therefore, the second latch circuit 132 stops sensing the combined clock signal CLK3 after the rising edge REIA of the transformed clock signal CKI is produced, ensuring that the falling edge FEIA of the transformed clock signal CKI can be controlled by the second reset signal SIG_{RST2}.

Subsequently, the second enable signal SIG_{EN2} can change from the low voltage to the high voltage before the next rising edge RE3B of the combined clock signal CLK3 is received. The second enable signal SIG_{EN2} then changes from the high voltage to the low voltage after the rising edge REIB of the transformed clock signal CKI is produced, ensuring that the falling edge FEIB of the transformed clock signal CKI can be controlled by the second reset signal SIG_{RST2}.

In some embodiments, to further control the second latch circuit 132, the second logic circuit 136 may receive some other system signals and enable the second latch circuit 132 only when needed. For example, the sleep signal SIG_{SLP}, the chip enable signal SIG_{CE}, and the write multiplex signal SIG_{WM} mentioned above may also be adopted by the second logic circuit 136 for generating the second enable signal SIG_{EN2} with the desired waveform.

Furthermore, as shown in FIG. 5, to provide a better driving ability and preserve the desired waveform, the second clock generator 130 further includes a buffer BFF to strengthen the transformed clock signal CKI.

Since the interface transformer 100 can generate the transformed clock signal CKI having two pulses in each cycle of the input clock signal CLK0, the one-port storage circuit 12 is able to perform two operations in each cycle of the input clock signal CLK0 according to the two pulses of the transformed clock signal. Therefore, the storage device 10 can be adopted as a pseudo two-port storage device. Furthermore, with the self-propagation scheme, each of the first clock generator 110 and the second clock generator 130 can utilize one latch for generating the clock signals, thereby making the interface transformer 100 even more hardware-efficient. Therefore, the hardware overhead for transforming the one-port storage circuit 12 into a pseudo two-port storage device is rather small.

In some embodiments, the storage circuit 12 can be a register file or a static random-access memory (SRAM) that includes a plurality of one-port storage cells. However, in some other embodiments, a two-port storage circuit can also be coupled to an interface transformer and become a pseudo four-port storage device.

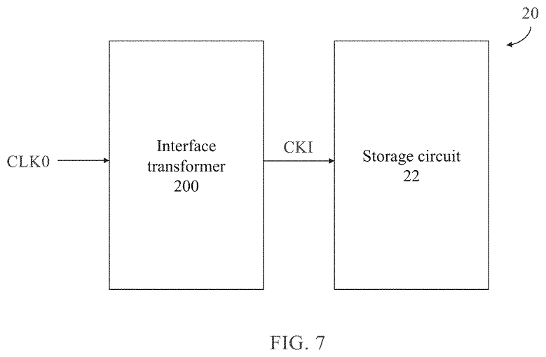

FIG. 7 shows a pseudo multiport storage device 20 according to another embodiment of the present disclosure. The pseudo multiport storage device 20 includes an interface transformer 200 and a storage circuit 22. The interface transformer 200 can have the same structure as the interface transformer 100. In the present embodiment, the storage circuit 22 is a two-port storage circuit. With the interface transformer 100, the storage circuit 22 can perform two read operations and two write operations during a cycle of the input clock signal CLK0 when operating in a two-read-two-write mode. In this way, the storage device 20 can be utilized as a pseudo four-port storage device.

In summary, the interface transformer and the multiport storage device provided by the embodiments of the present disclosure can generate a transformed clock signal having double pulses within a cycle of the input clock signal, thereby allowing the storage circuit to perform more operations within each cycle of the input clock signal. Furthermore, since the interface transformer adopts a self-propagation scheme, the hardware overhead of the present disclosure is rather small.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. An interface transformer comprising:
a first clock generator configured to generate an intermediate clock signal according to at least an input clock signal, wherein a rising edge of the input clock signal precedes a rising edge of the intermediate clock signal, and a falling edge of the intermediate clock signal precedes a falling edge of the input clock signal;
a combinational circuit configured to generate a mask clock signal by at least delaying the intermediate clock signal; and
a second clock generator configured to generate a transformed clock signal having a first pulse and a second pulse according to at least the input clock signal and the mask clock signal, wherein the first pulse and the second pulse arise within a cycle of the input clock signal.

2. The interface transformer of claim 1, wherein the first clock generator comprises:
a first latch circuit having a clock positive terminal configured to receive the input clock signal, a reset terminal configured to receive a first reset signal, and an output terminal configured to output the intermediate clock signal;
wherein:
the first latch circuit is configured to be triggered by the rising edge of the input clock signal to generate a rising edge of the intermediate clock signal; and
the first latch circuit is further configured to be reset and generate a falling edge of the intermediate clock signal when the first reset signal changes to a low voltage.

3. The interface transformer of claim 2, wherein the first latch circuit further includes an enable terminal configured to receive a first enable signal, wherein the first latch circuit is further configured to sense the rising edge of the input clock signal when the first enable signal is at a high voltage and stop sensing the rising edge of the input clock signal when the first enable signal is at a low voltage.

4. The interface transformer of claim 3, wherein the first clock generator further comprises a first logic circuit configured to generate the first enable signal according to at least the input clock signal and the intermediate clock signal.

5. The interface transformer of claim 2, wherein the first clock generator further comprises a first delay and inverse circuit configured to generate the first reset signal by delaying and inverting the intermediate clock signal.

6. The interface transformer of claim 1, wherein the second clock generator comprises:
an OR logic circuit configured to generate a combined clock signal according to the input clock signal and the mask clock signal; and
a second latch circuit having a clock positive terminal configured to receive the combined clock signal, a reset terminal configured to receive a second reset signal, and an output terminal configured to output the transformed clock signal;
wherein:
the second latch circuit is configured to be triggered by a rising edge of the combined clock signal attributed to the input clock signal to generate a rising edge of the first pulse of the transformed clock signal, and triggered by a rising edge of the combined clock signal attributed to the mask clock signal to generate a rising edge of the second pulse of the combined clock signal; and
the second latch circuit is further configured to be reset and generate a falling edge of the transformed clock signal when the second reset signal changes to a low voltage.

7. The interface transformer of claim 6, wherein the second latch circuit further includes an enable terminal configured to receive a second enable signal, wherein the second latch circuit is further configured to sense the rising edge of the combined clock signal when the second enable signal is at a high voltage and stop sensing the rising edge of the combined clock signal when the second enable signal is at a low voltage.

8. The interface transformer of claim 7, wherein the second clock generator further comprises a second logic circuit configured to generate the second enable signal according to at least the input clock signal and the transformed clock signal.

9. The interface transformer of claim 6, wherein the second clock generator further comprises a second delay and inverse circuit configured to generate the second reset signal by delaying and inverting the transformed clock signal.

10. The interface transformer of claim 6, wherein the second clock generator further comprises a buffer configured to strengthen the transformed clock signal.

11. A pseudo multiport storage device comprising:
the interface transformer of claim 1; and
a storage circuit coupled to the interface transformer, configured to perform read operations and write operations according to the transformed clock signal.

12. The pseudo multiport storage device of claim 11, wherein the storage circuit is a one-port storage circuit configured to perform a read operation and a write operation during a cycle of the input clock signal in a read-write mode.

13. The pseudo multiport storage device of claim 12, wherein the storage circuit is configured to perform a read operation according to the first pulse and perform a write operation according to the second pulse when operating in the read-write mode.

14. The pseudo multiport storage device of claim 12, wherein the storage circuit is configured to:
perform a read operation according to the first pulse and be idle during the second pulse when operating in a read mode; and
perform a write operation according to the second pulse and be idle during the first pulse when operating in a write mode.

15. The pseudo multiport storage device of claim 11, wherein the storage circuit is a register file or a static random-access memory.

16. The pseudo multiport storage device of claim 11, wherein the storage circuit is a two-port storage circuit configured to perform two read operations and two write operations during a cycle of the input clock signal when operating in a two-read-two-write mode.

17. The pseudo multiport storage device of claim 11, wherein the first clock generator comprises:
a first latch circuit having a clock positive terminal configured to receive the input clock signal, a reset terminal configured to receive a first reset signal, and an output terminal configured to output the intermediate clock signal;
wherein:
the first latch circuit is configured to be triggered by the rising edge of the input clock signal to generate a rising edge of the intermediate clock signal; and
the first latch circuit is further configured to be reset and generate a falling edge of the intermediate clock signal when the first reset signal changes to a low voltage.

18. The pseudo multiport storage device of claim 17, wherein the first clock generator further comprises a first delay and inverse circuit configured to generate the first reset signal by delaying and inverting the intermediate clock signal.

19. The pseudo multiport storage device of claim 11, wherein the second clock generator comprises:
an OR logic circuit configured to generate a combined clock signal according to the input clock signal and the mask clock signal; and
a second latch circuit having a clock positive terminal configured to receive the combined clock signal, a reset terminal configured to receive a second reset signal, and an output terminal configured to output the transformed clock signal;
wherein:
the second latch circuit is configured to be triggered by a rising edge of the combined clock signal attributed to the input clock signal to generate a rising edge of the first pulse of the transformed clock signal, and triggered by a rising edge of the combined clock signal attributed to the mask clock signal to generate a rising edge of the second pulse of the combined clock signal; and
the second latch circuit is further configured to be reset and generate a falling edge of the transformed clock signal when the second reset signal changes to a low voltage.

20. The pseudo multiport storage device of claim 19, wherein the second clock generator further comprises a second delay and inverse circuit configured to generate the second reset signal by delaying and inverting the transformed clock signal.
